(19) United States
(12) Patent Application Publication
(10) Pub. No.: US 2024/0372043 A1
(43) Pub. Date: Nov. 7, 2024

(54) METHOD FOR PRODUCING A PHOTOEMITTING OR PHOTORECEIVING DIODE

(71) Applicant: Lumileds LLC, San Jose, CA (US)

(72) Inventors: Ludovic Dupre, Grenoble Cedex 09 (FR); Helene Fournier, Grenoble Cedex 09 (FR); Franck Henry, Grenoble Cedex 09 (FR)

(73) Assignee: Lumileds LLC, San Jose, CA (US)

(21) Appl. No.: 18/775,755

(22) Filed: Jul. 17, 2024

Related U.S. Application Data
(63) Continuation of application No. 17/073,737, filed on Oct. 19, 2020.

(30) Foreign Application Priority Data
Oct. 28, 2019 (FR) 1912074

(51) Int. Cl. H01L 33/44; H01L 27/146; H01L 27/15; H01L 31/0216; H01L 31/0224; H01L 31/18; H01L 33/00; H01L 33/38

(52) U.S. Cl. CPC H01L 33/44; H01L 27/14643; H01L 27/156; H01L 31/02161; H01L 31/022408; H01L 31/1892; H01L 33/0093; H01L 33/385; H01L 2933/0016; H01L 2933/0025

(57) ABSTRACT

A method for producing a photoemitting or photoreceiving diode includes producing, on a first substrate, first and second semiconductor layers with opposite dopings, and a third intrinsic semiconductor layer; etching trenches surrounding remaining portions of the second and third layers and of a first part of the first layer; and producing, in the trenches, a dielectric spacer covering side walls of said remaining portions. The method also includes etching to extend the trenches as far as the first substrate; laterally etching a part of the dielectric spacer, exposing contact surfaces of the second part of the first layer; and producing, in the trenches, a first electrode in contact with the contact surfaces of the second part of the first layer and with lateral flanks of the second part of the first layer.

### CROSS-REFERENCE TO RELATED APPLICATIONS

This application is a Continuation of U.S. application Ser. No. 17/073,737, filed on Oct. 19, 2020, which claims priority to French Application No. 19 12074, filed Oct. 28, 2019, the entire disclosures of which are hereby incorporated by reference herein.

### TECHNICAL FIELD

This document relates to the field of photoemitting diodes or light emitting diodes (referred to as LEDs, or micro-LEDs or μLEDs when the dimensions therefore are a few micrometers or a few tens of micrometers) as well as the field of photoreceiving diodes or photodiodes. It applies in particular to the field of devices for lighting by LEDs, light-emissive electronic devices comprising matrices of LEDs such as screens, projectors, car headlights or image walls, and to the field of photoreceiving electronic or microelectronic devices including matrices of photodiodes, such as image sensors. It relates in particular to the manufacture of matrices of LEDs or μLEDs from a stack of GaN/InGaN semiconductors for producing display screens or matrix lighting.

### PRIOR ART

The production of diodes, for example in the production of a matrix of photodiodes or LEDs forming a matrix of pixels, is generally based on the implementation of standard microelectronic methods used commonly in so-called planar technology and during which each element of the diodes is produced by a deposition step and then a lithography step followed by an etching step. With this type of method, the production of each pattern of a material of the diodes requires the implementation of at least three distinct steps. In addition, each pattern produced must be aligned with those previously produced. Finally, the definition of each pattern must take into account the performances of the equipment concerned both in terms of both achievable dimensions and alignment performances with respect to the previous pattern.

In addition, in order to obtain sufficient performances with standard microelectronic technologies, planarization of the elements produced is necessary in order to master the lithography steps implemented on these elements since the resolution achievable with a lithography step is directly related to the topography on which this lithography is implemented, the optical lenses with very large apertures used in lithographic insolation devices having depths of field that decrease with the increase in resolution.

The document FR 3 042 913 A1 describes a method for the autoaligned manufacture of matrices of LEDs or μLEDs. In this method, the pixels are produced in an autoaligned fashion, that is to say by means of a single lithography level for physically separating the various LEDs while creating the mesa structures of the LEDs. The trenches produced also make it possible to take the electrical contact on one of the n or p doped parts of the LEDs solely by a contact with the lateral flanks of this part. These optical isolation trenches between pixels are etched as far as the growth substrate of the semiconductor forming the p-n junction of the LEDs and then filled with a material forming a reflective metallic electrode, which makes it possible to properly optically isolate the pixels from each other since the light emitted by a pixel is then directly extracted under this pixel and is not guided in the semiconductor to an adjacent pixel (crosstalk phenomenon). Thus this pixel matrix structure provides an optimum optical contrast and a good optical definition of the pixels.

However, from the electrical point of view, it is preferable for the electrical contact between the semiconductor of the n or p doped part located on the substrate and the electrodes providing the optical isolation not to take place on the lateral flanks of this part but for example on the surface parallel to the substrate, because of the better electrical properties of the crystalline planes parallel to the growth surface. This makes it possible to obtain a better electrical response, that is to say a higher electric current for the same operating voltage and therefore, in the case of photoemitting diodes, a larger quantity of light emitted for the same electrical power injected. On the other hand, producing the electrical contact at a surface parallel to the substrate involves not etching the semiconductor as far as the substrate in order to preserve a part at the bottom of the trenches, which degrades the optical isolation between the pixels, that is to say increases the crosstalk between the pixels. This is described in the document “Processing and characterization of high resolution GaN/InGaN LED arrays at 10 micron pitch for micro display applications” by L. Dupré et al., Proc. SPIE 10104, Gallium Nitride Materials and Devices XII, 1010422, 2017.

A compromise must therefore be achieved between the optical isolation of the pixels and the electrical response obtained.

In the document FR 2 992 465 A1, an LED device is produced from a stack of semiconductor layers prestructured in the form of independent elements, each element being used to produce an LED of the device. The production of the anode of each LED includes the etching of an opening of a dielectric layer previously deposited on the p-type semiconductor. In order to ensure good geometric definition of this electrode, it is necessary to produce this opening by plasma-assisted dry etching. However, the InGaN used for producing this device is a wide-gap semiconductor that is impaired by this type of etching, which leads to a poor electrical interface and therefore to an irreversible degradation of the electrical properties of the LEDs. Moreover, the method described in this document involves implementing photolithography steps requiring a precise alignment that is constraining compared with an auto-aligned method that has no limitation of alignment and therefore of minimum dimension of the structures manufactured.

### DISCLOSURE OF THE INVENTION

There is a need to propose a diode the structure of which makes it possible to reconcile good optical isolation between pixels and a good electrical response of the pixels, which can be implemented in an autoaligned manner and without degradation of its electrical properties.

For this purpose, one embodiment proposes a method for producing at least one photoemitting or photoreceiving diode, including at least:
producing, on a first substrate, at least one stack comprising first and second semiconductor layers doped according to opposite conductivity types, and at least a third layer of intrinsic semiconductor, or not intentionally doped semiconductor, disposed between the first and second layers, the first layer being disposed between the first substrate and the third layer;
etching trenches passing through the second and third layers and a first part of the first layer, surrounding remaining portions of the second and third layers and of the first part of the first layer, and such that bottom walls, or bottom, of the trenches are formed by a second part of the first layer disposed between the first part of the first layer and the first substrate;
producing, in the trenches, at least one dielectric spacer covering side walls of said remaining portions;
etching extending the trenches through the portions of the second part of the first layer not covered by the dielectric spacer, as far as the first substrate;
laterally etching a part of the dielectric spacer, exposing contact surfaces, for example horizontal, of the second part of the first layer;
producing, in the trenches, at least one first electrode in contact with the contact surfaces of the second part of the first layer and with lateral flanks, or sidewalls or lateral sides, of the second part of the first layer.

Because the first layer extends as far as the first substrate, the optical isolation of the diode is very effective. When this diode forms a pixel comprising adjacent pixels, good optical isolation between pixels is therefore obtained, which makes it possible to avoid light interactions between the adjacent diodes.

In addition, because the first electrode is electrically connected to the semiconductor of the remaining portion of the first layer by means of the side walls of the second part of the first layer and by means of the contact surfaces formed by the lateral etching of the dielectric spacer, a good electrical response of the diode is also obtained.

This diode uses a dielectric spacer, that is to say an electrical-insulation element, covering the lateral flanks of some of the elements forming the p-n junction of the diode and making it possible to electrically insulate and to passivate these lateral flanks, in particular vis-à-vis the first electrode, and also to electrically insulate the doped semiconductor portions of the p-n junction vis-à-vis each other. This dielectric spacer also makes it possible to provide the electrical insulation between the first electrode and the second electrode while occupying a minimum amount of space in the diode. This location of the dielectric spacer on the lateral flanks of the p-n junction of the diode makes it possible to improve the ratio between the active surface of the diode (the surface occupied by the p-n junction) and the total surface occupied by the diode, and therefore to reduce the overall size thereof.

In addition, this high integration of the dielectric spacer also has the advantage of minimizing the current densities obtained in the electrodes of the diode, and therefore reducing the heating by Joule effect generated in the diode via an overall reduction in the thermal resistance of the diode.

The structure of this diode makes it possible to reduce the manufacturing cost thereof as well as the energy consumption thereof. In the lighting field, such a diode improves the electrical injection obtained and therefore increases the energy efficiency thereof. In the field of imaging devices, such a diode makes it possible to produce high-resolution devices by reducing the size of the pixels, which becomes limited solely by the formation means used.

The term “layer” is used here and in the remainder of the document to designate a single layer or a stack of a plurality of layers.

The p-n junction which is made and the dielectric spacer form a mesa structure. The expression “mesa structure” designates the fact that the diode is produced in the form of a stack of doped semiconductor portions, a junction region comprising intrinsic semiconductor being arranged between these doped semiconductor portions, and that this stack is here etched over the entire height thereof in the form of an element referred to as a mesa.

The dielectric spacer being deposited on the lateral flanks of the structure etched in the stack of layers, this dielectric spacer can be produced by an auto-aligned method making it possible to isolate the electrodes of the diode without using a mask specially adapted to the production of this dielectric spacer, for example via a conformal deposition of the material of the dielectric spacer and then an etching, for example anisotropic, of the portions of this dielectric material that do not cover the lateral flanks of the structure.

The bottom walls of the trenches may be horizontal.

The first semiconductor layer may be n doped and the second semiconductor layer may be p doped, and the first electrode in this case can form a cathode of the diode.

The diode produced may, on the side opposite to the one where the first substrate is located, include a substantially planar continuous surface. This substantially planar continuous surface makes it possible to easily, for example without using inserts such as connection microbeads, hybridize the diode to another element such as a substrate making it possible to produce various connection configurations of the diode and also able to include a planar face on which materials analogous to those of the diode are located, for example by metal-to-metal direct bonding (for the electrodes) and dielectric against dielectric bonding (in particular for the dielectric spacer). This substantially planar continuous surface is also well adapted for producing an interconnection structure directly on the electrodes, thus avoiding many difficulties related to the residual topology of the structures of the diodes of the prior art.

The expression “substantially planar” is here used to designate the fact that the surface thus formed may exhibit variations in height, or thickness, between approximately 0 and 150 nm. These slight variations in height or thickness may originate in the implementation of chemical mechanical planarization (CMP) implemented in the presence of the materials of the electrodes and dielectric materials, the etching speeds of these various materials being different from each other. These slight variations in height or thickness may have the advantage of guaranteeing excellent isolation between the electrodes of the diode and/or vis-à-vis electrodes of adjacent diodes when hollows are formed at the top faces of the electrodes.

The first semiconductor layer may include a stack of at least two semiconductors doped according to different conductivity levels. For example, when the first semiconductor layer is n doped, it may include a stack of a first n+ doped semiconductor disposed on the first substrate and a second n− doped semiconductor disposed on the first semiconductor.

The diode may be a photodiode or a LED. When the diode is a LED, it may include a plurality of third intrinsic semiconductor layers forming an emissive active region with at least one quantum well disposed between the semiconductors of the first and second layers.

The lateral etching used here is an etching reducing the thickness of at least part of the dielectric spacer.

The dielectric spacer may, before the lateral etching is implemented, have an initial thickness greater than or equal to approximately 1 μm.

The part of the dielectric spacer removed during the lateral etching may have a thickness of between approximately 10 nm and an initial thickness of the spacer minus approximately 10 nm, so that the remaining spacer thickness is sufficient to ensure good electrical insulation.

The contact surfaces of the second part of the first layer may be substantially perpendicular to the side walls of said remaining portions.

The method may further include, between the production of the stack and the etching of the trenches through the second and third layers and the first part of the first layer, the production of at least one etching mask disposed on the stack and having a pattern corresponding to that of the trenches, and the dielectric spacer may be produced also covering the side walls of the etching mask.

In a first embodiment, the lateral etching of part of the dielectric spacer is an isotropic etching.

The etching mask may include at least one material that is at least partially etched during the lateral etching of a part of the dielectric spacer. The dielectric spacer may include SiO₂.

In a second embodiment, the production of the dielectric spacer may include:
depositing at least one layer of a first dielectric material covering the side walls of said remaining portions;
depositing at least one layer of a second dielectric material covering the layer of the first dielectric material, the second dielectric material being chosen so that it has an etching speed greater than that of the first dielectric material during the lateral etching of a part of the dielectric spacer that is an anisotropic etching;
wherein the etching extending the trenches and the lateral etching of a part of the dielectric spacer may be implemented simultaneously during the same etching step.

The method may be such that:
the stack further includes at least one electrically conductive layer such that the second layer is disposed between the third layer and the electrically conductive layer (this electrically conductive layer may be disposed between the second layer and an etching mask when an etching mask is used);
the etched trenches pass through the electrically conductive layer and surround at least one remaining portion of the electrically conductive layer forming a first part of a second electrode;
the dielectric spacer covers side walls of the first part of the second electrode; and
and the method may further include, after the lateral etching of a part of the dielectric spacer, a step of producing a second part of the second electrode.

In this case, the production of the first electrode and of the second part of the second electrode may include at least:
producing at least one opening through the stack and emerging on the first part of the second electrode;
depositing at least one electrically conductive material in the opening and in the trenches; and
planarizing the electrically conductive material.

In this case, the production of the electrodes corresponds to the implementation of a “damascene” type method wherein one or more electrically conductive materials are formed by at least one full-wafer deposition, that is to say a deposition of the electrically conductive material over the whole of the structure produced, the electrodes next being obtained via a planarization of this or these electrically conductive materials. The production of the first electrode therefore does not require a specific alignment step or particular masking step. The location of the first electrode may correspond to a space formed by the trenches between adjacent diodes.

The method may further include, after the production of the first electrode and of the second part of the second electrode, a transfer of the photoemitting or photoreceiving diode onto an interconnection substrate such that the first and second electrodes of the photoemitting or photoreceiving diode are electrically connected to the interconnection substrate, and then a step of removing the first substrate.

The electrically conductive layer may be optically reflective, that is to say may have an amplitude reflection coefficient (the ratio of the amplitude of the reflective light to the amplitude of the incident light) of at least 80%. In this case, the second electrode, which is disposed on the side opposite to the one through which the light is intended to enter or leave the diode, may be optically reflective. Thus the light may enter or leave the diode without having to pass through a transparent electrode, for example comprising a conductive transparent oxide such as ITO, which gives rise to optical losses of the light emitted or received.

Another embodiment relates to a method for producing an electronic device, including the implementation of a method as described above, wherein the steps implemented form a plurality of photoemitting diodes and/or a plurality of photoreceiving diodes in which the first electrodes of said diodes are electrically connected together.

According to a particular configuration, the first electrodes of the diodes of the device may form a cathode common to these diodes.

The diodes may form part of a matrix of diodes with similar structures forming a matrix of pixels of the electronic device.

### BRIEF DESCRIPTION OF THE DRAWINGS

The present invention will be understood better from a reading of the description of example embodiments given purely indicatively and in no way limitatively, referring to the accompanying drawings, on which:

FIGS. 1A to 1J show the steps of a method for producing an electronic device, including a method for producing a photoemissive or photoreceiving diode, according to a first embodiment;

FIGS. 2A and 2B show photographs of a structure obtained when use is made of an isotropic lateral etching of an etching mask similar to that used during the method for producing a photoemissive or photoreceiver diode, according to the first embodiment; and

FIGS. 3A and 3B show some of the steps of a method for producing an electronic device, including a method for producing a photoemissive or photoreceiver diode, according to a second embodiment.

Identical, similar or equivalent parts of the various figures described below bear the same numerical references so as to facilitate passing from one figure to another.

The various parts shown in the figures are not necessarily shown to a uniform scale, in order to make the figures more legible.

The various possibilities (variants and embodiments) must be understood as not being exclusive of one another and may be combined with one another.

### DETAILED DESCRIPTION OF PARTICULAR EMBODIMENTS

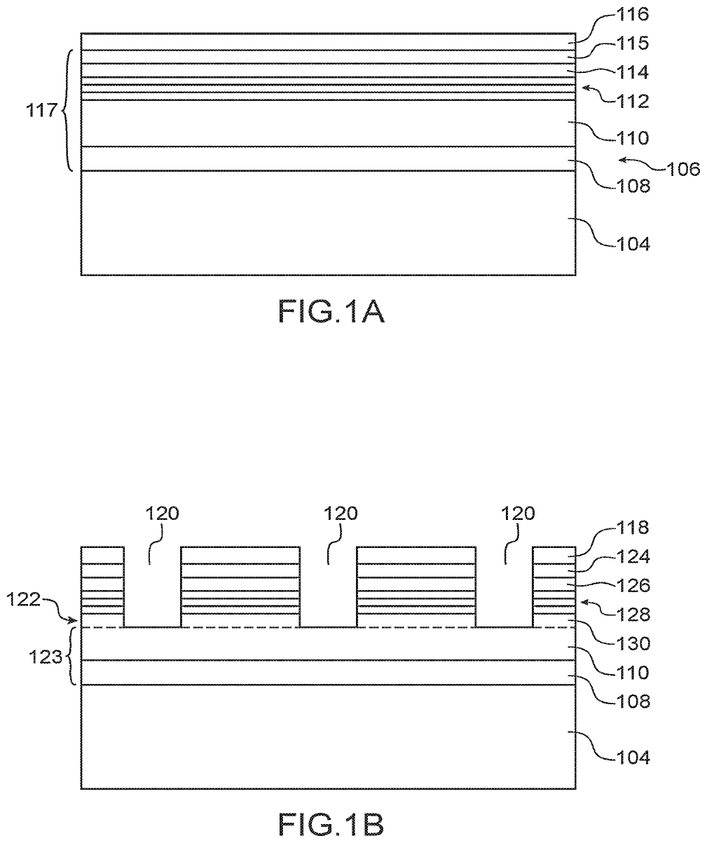

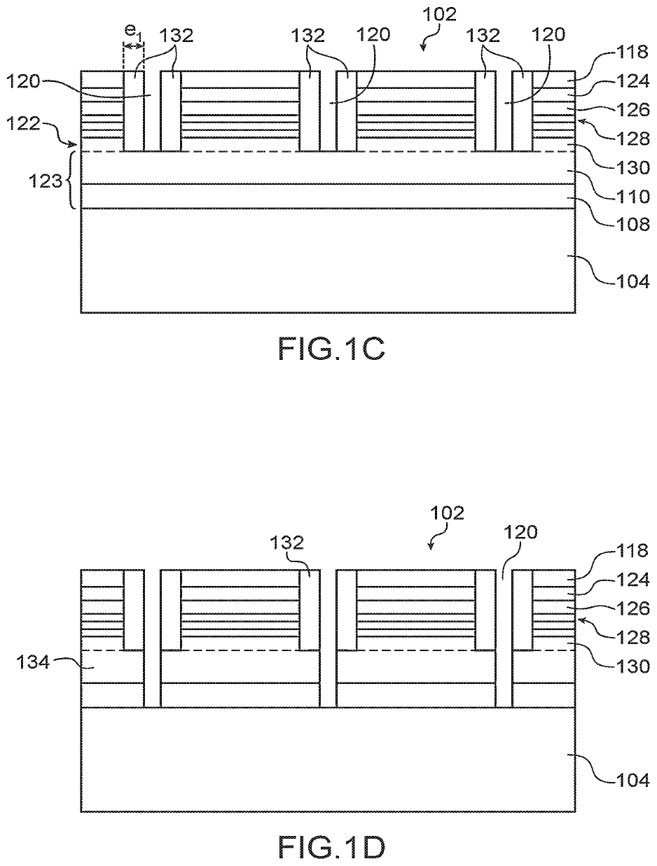

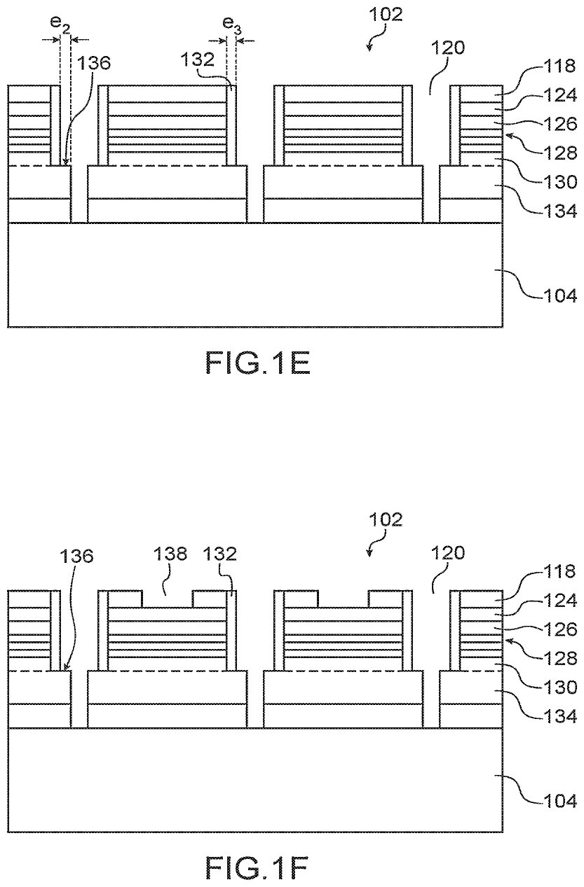

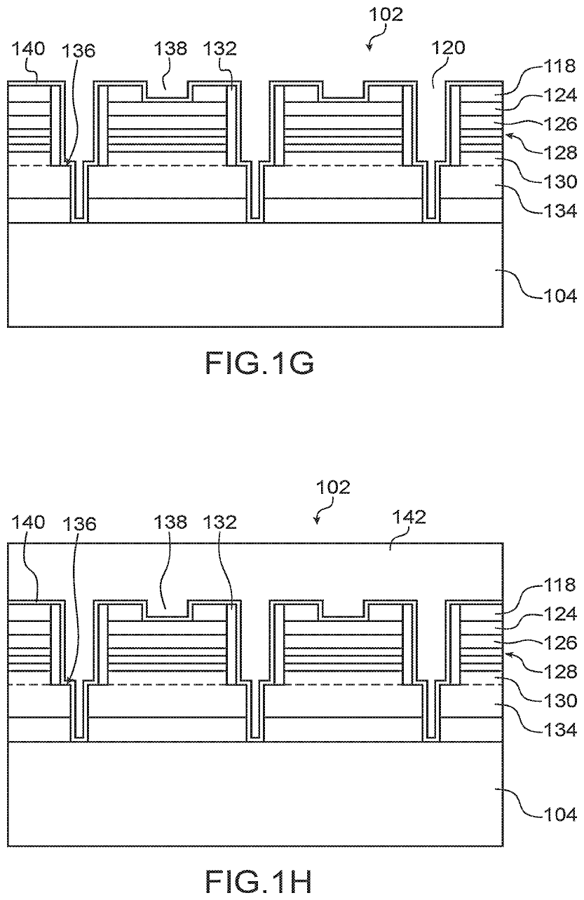

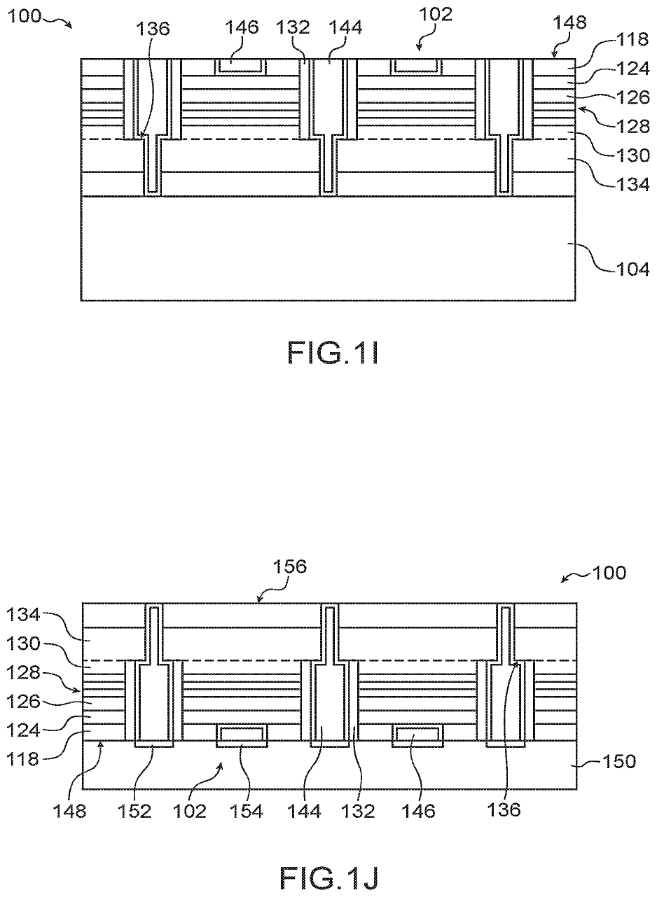

FIGS. 1A to 1J show the steps of a method for producing an electronic device 100 according to a first embodiment. In the first embodiment described here, the device 100 includes a plurality of diodes 102 corresponding here to photoemissive or light-emitting diodes.

As shown in FIG. 1A, the device 100 is produced from a first substrate 104 comprising for example sapphire, silicon, a semiconductor similar to the one used for forming the active part of the diodes 102, or any other material enabling the first substrate 104 to form a growth substrate for the deposition of a semiconductor stack from which the diodes 102 will be produced. The first substrate 104 is used as a support for the deposition or growth of layers intended for producing the diodes 102 of the device 100.

A first layer 106 of semiconductor doped according to a first conductivity type, for example n type, is produced on the first substrate 104.

According to a particular example embodiment, this first layer 106 corresponds to a stack of a plurality of distinct semiconductor layers, for example a layer 108 of n+ doped semiconductor with a donor concentration for example of between approximately 5.10¹⁷ and 5.10²⁰ donors/cm³, on which another layer 110 of n− doped semiconductor with a donor concentration of for example between approximately 10¹⁷ and 5.10¹⁹ donors/cm³ is disposed. For example, the layer 108 may include GaN and the layer 110 may include InGaN. The thickness of the layer 108 is for example greater than approximately 100 nm, for example equal to approximately 3 μm, and the thickness of the layer 110 is for example between approximately 5 nm and 500 nm. The total thickness of the first layer 106, that is to say the sum of the thicknesses of the layers 108 and 110 in this particular example embodiment, is for example between approximately 20 nm and 10 μm, and preferably between approximately 2 μm and 4 μm. The layer 108 forms here a buffer layer disposed between the layer 110 and the first substrate 104 and is used in particular to filter the growth defects in order for these defects not to be located in the layer 110 which is used to form the p-n junctions of the diodes 102.

In a variant, the layers 108 and 110 may be doped with the same doping level.

According to another variant, the layer 106 may correspond to a single semiconductor layer. This single semiconductor layer is for example n doped and may have a donor concentration for example of between approximately 10¹⁷ and 5.10²⁰ donors/cm³. By way of example, this layer may include GaN and the thickness thereof is for example between approximately 20 nm and 10 μm, and advantageously between approximately 2 μm and 4 μm.

According to another variant, the layer 106 may correspond to a stack of a plurality of distinct semiconductor layers, for example a layer 108 of intentionally non-doped semiconductor forming a buffer layer disposed between the layer 110 and the first substrate 104, on which the layer 110 of n doped semiconductor with a donor concentration of for example between approximately 10¹⁷ and 5.10²⁰ donors/cm³ is disposed. The thickness of the layer 108 is for example greater than approximately 100 nm, for example equal to approximately 3 μm, and the thickness of the layer 110 is for example between approximately 100 nm and 3 μm.

One or more third layers 112 of intrinsic semiconductor, that is to say intentionally non-doped (with a residual donor concentration n_{nid} for example equal to approximately 10¹⁷ donors/cm³, or between 10¹⁵ and 10¹⁸ donors/cm³), are produced on the first layer 106 (on the layer 110 in the example shown in FIG. 1A). In the first embodiment described here, the third layers 112 are an active region comprising one or more emissive layers, for example five, intended each to form, in the diodes 102, a quantum well. These emissive layers include for example InGaN. Each emissive layer is disposed between two barrier layers, including for example GaN. The thickness of the or of each of the emissive layers is for example equal to approximately 3 nm and more generally between approximately 0.5 nm and 10 nm, and the thickness of each of the barrier layers is for example between approximately 1 nm and 25 nm.

A second layer 114 of semiconductor doped according to a second conductivity type, opposite to the doping type of the first layer 106 and therefore here of p type, with a concentration of acceptors for example between approximately 10¹⁷ and 5.10¹⁹ acceptors/cm³, is produced on the third layer or layers 112. The layers 106, 112 and 114 (and more particularly the layers 110, 112 and 114 in the example described here) are intended to form the p-i-n junctions of the diodes 102. The semiconductor of the second layer 114 is for example GaN and the thickness thereof is for example between approximately 20 nm and 10 μm.

In a variant embodiment, an electron-blocking layer (not shown in FIGS. 1A to 1J) may be disposed between the second layer 114 and the third layer or layers 112, this electron-blocking layer including for example AlGaN with 12% aluminum and being able to be p doped with a concentration of acceptors for example equal to approximately 1.10¹⁷ acceptors/cm³.

Materials other than those cited above may be used for producing the layers 106, 112 and 114. For example, the material of the emissive layers formed by the third layers 112 is chosen according to the required emission spectrum of the diodes 102.

An electrically conductive layer 115 intended to form, in each diode 102, a first part of a second electrode that will be in contact with the semiconductor of the second layer 114, is disposed on the second layer 114. The electrically conductive material used is advantageously optically reflective and is for example aluminum or silver.

A layer 116 intended to form an etching mask is produced on the layer 115. The material of this layer 116 is for example SiO₂.

The layers 106, 112, 114 and 115 form together a stack 117 from which the diodes 102 will be produced.

As shown in FIG. 1B, patterns are produced by lithography and etching (using for example a fluorinated plasma such as CHF₃ or SF₆) in the layer 116 so that the remaining portions of this layer 116 form an etching mask 118. The photolithography resin used for producing the etching mask 118 is next removed. The openings formed in the etching mask 118 correspond to the patterns of trenches to be etched in the layers of the stack 117 in order to define the mesa structures of the diodes 102.

An etching of trenches 120 passing through the electrically conductive layer 115, the second layer 114, the third layer or layers 112 and a first part 122 of the first layer 106 is implemented according to the pattern of the etching mask 118. This etching is stopped at a depth level located in the first layer 106 such that a second part 123 of the first layer 106 is preserved at the bottom of each of the etched trenches 120. In FIG. 1B, the first part 122 of the first layer 106 is delimited symbolically from the second part 123 of the first layer 106 by a dotted line. In the example described here, the etching is stopped at a level located in the layer 110 such that the layer 108 and a part of the thickness of the layer 110 are not etched. The thickness of the first layer 106 that is etched, that is to say the thickness of the first part 122 of the first layer 106, is for example between approximately 100 nm and 5 μm.

At the end of this etching, the trenches 120 surround:
the etching mask 118;
remaining portions 124 of the electrically conductive layer 115 intended to form first parts of the second electrodes of the diodes 102;
remaining portions 126 of the second layer 114 intended to form part of the p-n junctions of the diodes 102;
remaining portions 128 of the third layer or layers 112 intended to form the active regions of each diode 102, and
remaining portions 130 of the first part 122 of the first layer 106 intended to form, with the remaining portions 126 of the second layer 114, the p-n junctions of the diodes 102.

The layers 115, 112, 114 and 106 are etched by dry method, for example by a reactive ion etching performed with a plasma torch system, or ICP-RIE, standing for “Inductively Coupled Plasma-Reactive Ion Etching”.

A dielectric spacer 132 is next produced in the trenches 120 (see FIG. 1C). For this purpose, a dielectric layer is conformally deposited, for example by a deposition of the PECVD (plasma enhanced chemical vapor deposition) type, on the etching mask 118 and against the side walls and the bottom walls of the trenches 120. The parts of this dielectric layer that do not cover the side walls of the trenches 120, that is to say those located on the etching mask 118 and those located at the bottom of the trenches 120, are eliminated by an anisotropic etching, corresponding for example to a dry etching such as a RIE etching or reactive ion etching. The remaining portions of this dielectric layer form the dielectric spacer 132 that covers the side walls of the remaining portions 124, 126, 128 and 130 and those of the etching mask 118.

The dielectric spacer 132 has an initial thickness equal to that of the dielectric layer deposited. This thickness is great and is for example greater than or equal to approximately 1 μm. On this FIG. 1C, this initial thickness bears the reference “e1”. The thickness of the dielectric spacer 132 corresponds to the dimension perpendicular to the surface against which the material of the dielectric spacer 132 is deposited.

As shown in FIG. 1D, a second etching of the layer 106 is then performed, extending the trenches 120 as far as the first substrate 104, through the portions of the second part 123 of the first layer 106 that are not covered by the dielectric spacer 132. At the end of this second etching, the trenches 120 also surround remaining portions 134 of the second part 123 of the first layer 106.

The etching mask 118, the remaining portions 124, 126, 128, 130, 134 and the dielectric spacer 132 form mesa structures, that is to say stacks in the form of islands, disposed on the first substrate 104. Each mesa structure of each diode 102 has a cross-section in a plane parallel to the face of the first substrate 104 on which these structures rest, for example rectangular in shape. Each of the mesa structures may therefore form a parallelepipedal-shaped element. Mesa structures with a different shape are possible, for example cylindrical.

A lateral etching of a part of the dielectric spacer 132 is next implemented, exposing contact surfaces 136 of the second part 123 of the first layer 106 (see FIG. 1E). The contact surfaces 136 of the second part 123 of the first layer 106 exposed are preferably substantially horizontal, in the direction of orientation of the figures. The lateral etching therefore exposes crystal planes parallel to the growth surface having better electrical properties than the planes perpendicular to the growth surface. The part of the dielectric spacer 132 that is eliminated during this lateral etching has a thickness (referenced “e2” in FIG. 1E) of for example between approximately 10 nm and the initial thickness of the spacer (e1) minus approximately 10 nm, so that the remaining spacer thickness (referenced “e3”) is sufficient to ensure good electrical insulation. The thickness e2 is for example equal to approximately 600 nm when the dielectric spacer 132 has an initial thickness e1 equal to approximately 1 μm. The remaining part of the dielectric spacer 132 therefore has a thickness e3=e1−e2, and for example equal to 400 nm for the example described above.

In this first embodiment, the lateral etching of the dielectric spacer 132 implemented is an isotropic etching, for example a wet chemical etching or an isotropic plasma etching. During such an isotropic etching, the etching mask 118 is therefore also at least partially etched if the material of the etching mask 118 is sensitive to the etching agents used (this is the case in the example embodiment described here where the etching mask 118 and the dielectric spacer 132 include SiO₂).

Openings 138 are next produced through the etching mask 118, forming locations for producing second parts of the second electrodes of the diodes 102 (FIG. 1F). These openings 138 pass through the entire thickness of the etching mask 118 so that the bottom walls of the openings 138 are formed by the portions 124. This etching is for example of the ICP-RIE type.

A first electrically conductive material 140 is next deposited in the trenches 120, as well as on the top faces of the etching mask 118 and in the openings 138 (FIG. 1G). This first electrically conductive material 140 is conformally deposited, that is to say forming a layer of substantially constant thickness on the etching mask 118 and along the walls of the trenches 120 and of the openings 138. In the example embodiment described here, the first electrically conductive material 140 is formed by the deposition of a first layer of titanium with a thickness for example of between approximately 5 nm and 300 nm, followed by a deposition of a second layer of aluminum with a thickness of for example between approximately 50 nm and 1 μm. In a variant embodiment, the first electrically conductive material 140 is formed by a single layer of aluminum with a thickness of for example between approximately 50 nm and 1 μm.

The first electrically conductive material 140 deposited is in contact electrically with the lateral flanks of the portions 134 but also with the contact surfaces 136 that actively participate in the electrical contact with the semiconductor of the first layer 106 in addition to the contact with the lateral flanks of the portions 134. The electrically conductive material 140 is also in contact with the portions 124 at the bottom walls of the openings 138. These electrical contacts are intended to form electrical contacts between the p-n junctions and the anodes and cathodes of the diodes 102.

As shown in FIG. 1H, a second electrically conductive material 142 is deposited by filling the remaining volume of the trenches 120 and of the openings 138. In FIG. 1H, the thickness of this second electrically conductive material 142 is such that it also covers the parts of the first electrically conductive material 140 disposed on the etching mask 118. The second electrically conductive material 142 is for example copper, which can be formed by the implementation of a full-wafer electrochemical deposition (ECD), that is to say on the whole of the structure previously produced.

Finally, the diodes 102 of the device 100 are completed by performing a chemical-mechanical planarization (CMP) eliminating the portions of the first and second electrically conductive materials 140 and 142 that project beyond the trenches 120 and the openings 138 and which are disposed on the etching mask 118. This planarization electrically insulates the portions of conductive material disposed in the trenches 120 vis-à-vis those disposed in the openings 138 (FIG. 1I). The portions of the electrically conductive materials 140 and 142 disposed in the trenches 120 form first electrodes 144 (corresponding to cathodes in the example embodiment described here) extending over the entire height of the mesa structures of the diodes 102 and which are electrically connected to the semiconductor portions 134. The portions of the electrically conductive materials 140 and 142 disposed in the openings 138 form second parts of the second electrodes 146 (corresponding to anodes in the example described here) electrically connected to the portions 124 corresponding to the first parts of the second electrodes 146. The second electrodes 146 are connected to the portions 126 at the top faces of these portions 126.

This planarization also forms a face 148 of the device 100 that is substantially planar and formed by the top faces of the electrodes 144, 146, of the dielectric spacer 132 and of the etching mask 118. This face 148 forms the rear faces of the diodes 102 at which electrical connections with the electrodes 144, 146 will be made.

By means of the dielectric spacer 132, the first electrodes 144 are well insulated electrically from the semiconductor portions 124, from the second electrodes 146 and from the portions 128 forming the active regions of the diodes 102.

In order to guarantee electrical insulation between the electrodes 144, 146 of the diodes 102, and to avoid the presence of parts of the electrically conductive materials 140 and 142 electrically connecting one or more of the first electrodes 144 with one or more of the second electrodes 146, the planarization step may advantageously be performed until an overetching of the portions of the electrically conductive materials 140 and 142 disposed in the trenches 120 and in the openings 138 is achieved with respect to the dielectric materials of the dielectric spacer 132 and of the etching mask 118, forming, in the electrodes 144, 146, hollows at the top faces of these electrodes. These hollows may have a depth, with respect to the plane of the top face 148, of between approximately 5 nm and 150 nm. This overetching may be obtained by acting on the etching selectivity that exists between the dielectric materials of the spacer 132 and of the etching mask 118 and the electrically conductive materials 140 and 142. The CMP implemented has a different abrasion speed according to the materials and, in the method described here, the abrasion of the electrically conductive materials 140 and 142 is more rapid than the abrasion of the dielectric materials of the spacer 132 and of the etching mask 118. This results, at the top face 148 of the device 100, in a removal of the materials 140, 142 with respect to the dielectric spacer 132 and to the etching mask 118. Thus the electrodes 144, 146 of the diodes 102 remain perfectly isolated from each other by virtue of an intrinsic property of the planarization used. Such overetching may also be implemented by an RIE etching.

The substantially flat surface obtained at the top face 148 of the device 100 makes it possible to easily hybridize the matrix of diodes 102 produced with any type of connection element such as an electronic circuit, and makes it possible in particular to perform such hybridization by direct bonding, also referred to as molecular adhesion bonding, of the matrix of diodes 102 to the electronic circuit without using inserts, such as microbeads, between the matrix of diodes 102 and the electronic circuit. Direct bondings of the metal-metal and dielectric-dielectric type made in this case have the advantage of being impervious. The fact that these hollows are present at the top faces of the electrodes 144, 146 does not pose any problem for implementation of such direct bonding since, during this direct bonding, the materials of these portions expand and it is therefore possible to obtain very good contact between these electrodes and conductive elements of the electronic circuit. Details of implementation of such direct bonding are for example described in the document “Mechanisms of copper direct bonding observed by in-situ and quantitative transmission electron microscopy” by M. Martinez et al., Thin Solid Films 530 (2013) 96-99.

As shown in FIG. 1J, the matrix of diodes 102 is transferred, at the top face 148 thereof, onto an interconnection substrate 150 including electrical contacts 152 and 154 to which the electrodes 144, 146 can be electrically connected, for example via direct bonding as described above. This interconnection substrate 150 may be an electronic circuit on to which the matrix of diodes 102 is transferred.

The method here described and the substantially flat surface obtained at the top face 148 of the device 100 is also compatible with the conventional hybridization methods using for example inserts, such as microbeads or microtubes, for hybridizing the matrix of diodes 102.

After this transfer, the first substrate 104 can be removed, thus leaving clear a front face 156 of the diodes 102 through which the light is intended to enter or leave (leave in the example described here, where the diodes 102 are LEDs). The type of removal implemented depends in particular on the nature of the first substrate 104. For example, in the case of a first sapphire substrate 104, this can be removed by lift-off. It is also possible for the first substrate 104 to be removed by grinding, or by selective etching.

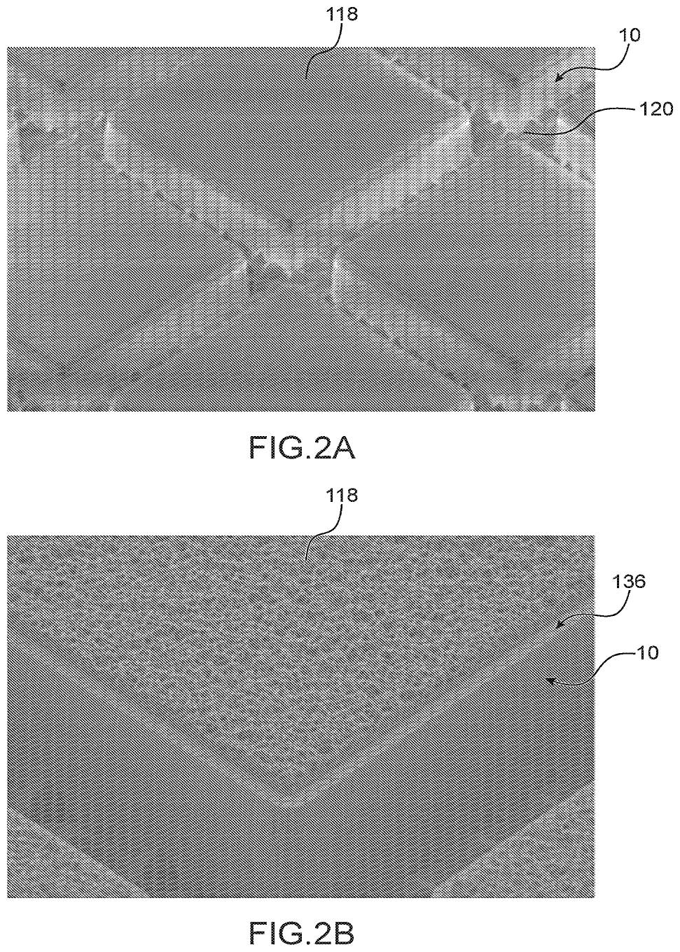

In order to illustrate the lateral etching implemented during the method described above, FIGS. 2A and 2B show images obtained by electron microscopy during such lateral etching.

FIG. 2A shows semiconductor mesa structures 10 with a geometry similar to those formed by the portions 124, 126, 128, 130 and 134 and the etching mask 118 after having etched the trenches 120. FIG. 2B shows the contact surface 136 obtained by the partial lateral removal of the etching mask 118 after having implemented an isotropic lateral etching, here by chemical method.

A description is given below of the steps of a method for producing an electronic device 100 according to a second embodiment. In the second embodiment described here, the device 100 includes a plurality of diodes 102 which are, in this second embodiment, light-emitting diodes.

The steps previously described in relation to FIGS. 1A and 1B are first of all implemented.

The dielectric spacer 132 is next produced in the trenches 120. Unlike the first embodiment in which the dielectric spacer 132 is produced by depositing a single thick layer of dielectric material, the dielectric spacer 132 is here produced by conformally depositing a layer 133 of a first dielectric material, this layer 133 in particular covering, in the trenches 120, the side walls of the portions 124, 126, 128 and 130 and of the etching mask 118. A layer 135 of a second dielectric material is next deposited by covering the layer 133. The first and second dielectric materials are chosen so that the second dielectric material has an etching speed greater than that of the first dielectric material during the lateral etching a part of the dielectric spacer that is then implemented, that is to say the anisotropic etching of the spacers and the etching of the semiconductor layers. For example, the first dielectric material of the layer 133 may be SiO₂ and the second dielectric material of the layer 135 may be SiN.

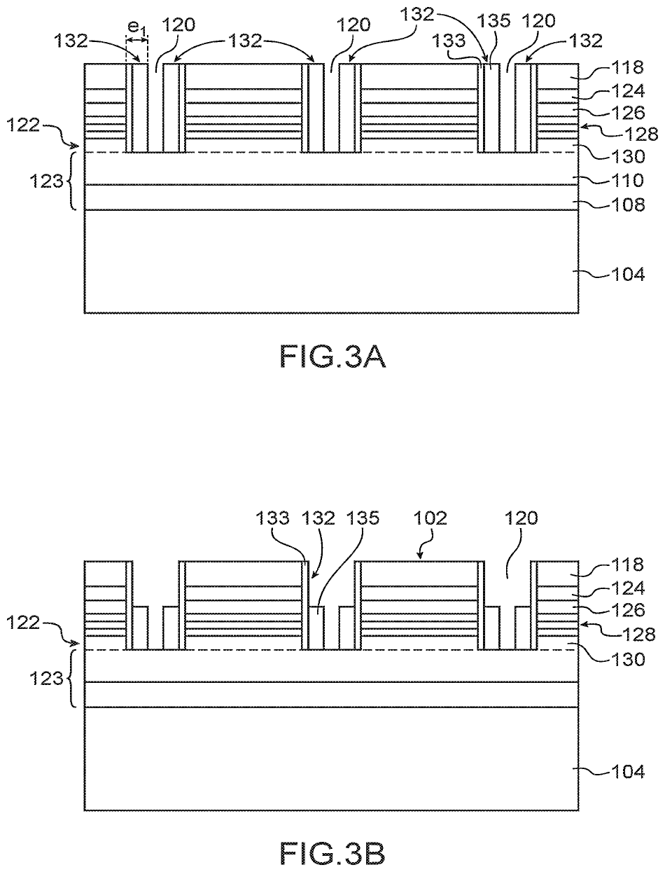

The portions of the layers 133 and 135 that do not cover the side walls of the trenches 120, that is to say those located on the etching mask 118 and those located at the bottom of the trenches 120, are removed by anisotropic etching, for example a dry etching such as an RIE etching. The remaining portions of these dielectric layers 133 and 135 form the dielectric spacer 132 that covers the side walls of the remaining portions 124, 126, 128 and 130 and of the etching mask 118 (see FIG. 3A). The difference in etching speed between the first and second dielectric materials during this anisotropic etching results in a difference in height between the layer 135 and the layer 133 after the manufacture of the dielectric spacer: the remaining portion of the layer 135 is smaller than the remaining portion of the layer 133.

A selective etching step may next be performed in order to remove part of the remaining portions of the layer 135. The structure obtained in this case is shown in FIG. 3B.

Another etching is next implemented in order to extend the trenches 120 as far as the first substrate 104, through portions of the second part 123 of the first layer 106 that are not covered by the dielectric spacer 132, that is to say not covered by the portions of the layers 133 and 135. At the end of this second etching, the trenches 120 also surround remaining portions 134 of the second part 123 of the first layer 106.

Implementation of this etching also removes the remaining portions of the layer 135. At the end of this etching, the dielectric spacer 132 is then formed only by the remaining portions of the layer 133. The surfaces left clear by the removal of the portions of the layer 135 form the contact surfaces 136 intended for the electrical contacts with the semiconductor of the portions 134. The structure obtained is therefore similar to that shown in FIG. 1E.

Before implementation of this etching extending the trenches, the height of the portions of the layer 135 that have been preserved is adapted according in particular to the thickness of the etching mask 118, the thicknesses of the various etched semiconductor layers, or the selectivity of etching of the various materials, and this for the purpose that throughout the etching extending the trenches the contact surfaces 136 are properly protected by the portions of the layer 135 and that, at the end of this etching, the portions of the layer 135 are properly removed.

In a variant embodiment, part of the remaining portion of the layer 135 may remain after the etching extending the trenches, which it is then necessary to remove by means of an anisotropic etching that is selective with respect to the material of the layer 133.

The diodes 102 and the device 100 are next completed as in the first embodiment, performing the various steps previously described in relation to FIGS. 1F to 1J.

In the first and second particular embodiments described above, the semiconductor portions 130, 134 are of the n type and the second semiconductor portions 126 are of the p type. In a variant, the semiconductor portions 130, 134 may be of the p type and the second semiconductor portions 126 may be of the n type, with in this case the portions of electrically conductive material disposed in the trenches 120 forming the anodes of the diodes 102 and the portions of electrically conductive materials disposed in the openings 138 forming, with the portions 124, the cathodes of the diodes 102.

Furthermore, in the first and second embodiments described here, the previous steps performed are such that the contact surfaces 136 are substantially perpendicular to the lateral walls of the remaining portions 124, 126, 128, 130 and 134. In a variant, according to the geometry required for the diodes 102 and therefore the etchings used, it is possible for the contact surfaces 136 not to be perpendicular to these side walls.

In addition, in the first and second embodiments described above, the device 100 includes a matrix of diodes 102 that are light emitting diodes, the microelectronic device 100 being able to form part of a display device with LEDs (screens, projector, image wall, etc.). This matrix of diodes 102 includes the first electrodes 144 that form one and the same electrode common to all the diodes 102, and each diode 102 includes a second electrode 146 making it possible to perform the individual addressing of each of the diodes 102.

In a variant, the microelectronic device 100 may include a matrix of diodes 102 that are photoreceiving diodes, or photodiodes. In this variant, the electrodes 144, 146 do not serve to supply current to the diodes 102 but serve to recover the currents photogenerated by the diodes 102.

In a variant, the device 100 may include, on the top face 148, a connection structure different from the interconnection substrate 150, forming the electrical connections of the diodes 102 and including first electrically conductive elements electrically connected to the first electrodes 144 of the diodes 102 and second electrically conductive elements electrically connected to the second electrodes 146 of the diodes 102. These electrically conductive elements of such a connection structure are electrically insulated from each other by dielectric elements the dimensions of which, in the plane of the face 148, are at least equal to those of the dielectric spacer 132 and of the etching mask 118 so that the electrically conductive elements do not form a short-circuit between the electrodes of the diodes 102.

In the embodiments described above, the diodes 102 produced form a matrix of diodes serving as a matrix of pixels of the device 100. In a variant, the diodes 102 may be produced alongside each other without forming a matrix of diodes and/or without regular spacings between them.

What is claimed is:

1. A method for producing at least one photoemitting or photoreceiving diode, comprising:
producing, on a first substrate, at least one stack comprising first and second layers of semiconductor doped according to opposite conductivity types, and at least a third layer of intrinsic semiconductor disposed between the first and second layers, the first layer being disposed between the first substrate and the third layers;
etching trenches passing through the second and third layers and a first part of the first layer, surrounding remaining portions of the second and third layers of the first part of the first layer, and such that bottom walls of the trenches are formed by a second part of the first layer disposed between the first part of the first layer and the first substrate;
conformally depositing, in the trenches, at least one dielectric spacer covering side walls of said remaining portions and not covering top surfaces and bottom walls, the at least one dielectric spacer having a first thickness greater than or equal to 1 μm;
etching extending the trenches through portions of the second part of the first layer not covered by the at least one dielectric spacer, as far as the first substrate;
laterally etching part of the at least one dielectric spacer to form at least one thinned dielectric spacer having a second thickness between 10 nm and the first thickness minus 10 nm, exposing contact surfaces of the second part of the first layer; and
producing, in the trenches, by deposition of a metal to form at least one first electrode in direct electrical physical contact with the contact surfaces of the second part of the first layer and with lateral flanks of the second part of the first layer,
wherein the contact surface and the lateral flanks of the second part of the first layer contacted by the metal are formed from a same material having the same doping concentration.

2. The method according to claim 1, wherein the contact surfaces of the second part of the first layer are perpendicular to the side walls of said remaining portions.

3. The method according to claim 1, further comprising, between producing the stack and etching the trenches through the second and third layers and the first part of the first layer, forming at least one etching mask disposed on the stack and having a pattern corresponding to that of the trenches, and wherein the at least one dielectric spacer is conformally deposited by also covering side walls of the etching mask.

4. The method according to claim 1, wherein laterally etching a part of the at least one dielectric spacer comprises isotropic etching.

5. The method according to claim 3, wherein laterally etching the part of the at least one dielectric spacer comprises isotropic etching, and wherein the etching mask includes at least one material that is at least partially etched during laterally etching the part of the at least one dielectric spacer.

6. The method according to claim 1, wherein the at least one dielectric spacer comprises SiO₂.

7. The method according to claim 1, wherein conformally depositing the at least one dielectric spacer comprises:
depositing at least one layer of a first dielectric material covering the side walls of said remaining portions; and
depositing at least one layer of a second dielectric material covering the layer of the first dielectric material, the second dielectric material being chosen so that is has an etching speed greater than that of the first dielectric material during the lateral etching of a part of the at least one dielectric spacer that corresponds to an isotropic etching;
wherein the etching extending the trenches and the lateral etching of a part of the at least one dielectric spacer is implemented simultaneously during the same etching step.

8. The method according to claim 1, wherein:
the stack further includes at least one electrically conductive layer such that the second layer is disposed between the third layer and the at least one electrically conductive layer;
the etched trenches pass through the at least one electrically conductive layer and surround at least one remaining portion of the at least one electrically conductive layer forming a first part of a second electrode;
the at least one dielectric spacer covers side walls of the first part of the second electrode; and the method further comprises, after the lateral etching of a part of the at least one dielectric spacer, a step of producing a second part of the second electrode.

9. The method according to claim 8, wherein producing the at least one first electrode and the second part of the second electrode comprises:
producing at least one opening through the stack and emerging on the first part of the second electrode;
depositing at least one electrically conductive material in the opening and in the trenches; and
planarizing the at least one electrically conductive material.

10. The method according to claim 8, further comprising, after producing the at least one first electrode and the second part of the second electrode, transferring the at least one photoemitting or photoreceiving diode onto an interconnection substrate such that the first and second electrodes of the at least one photoemitting or photoreceiving diode are electrically connected to the interconnection substrate, and then a step of removing the first substrate.

11. The method according to claim 8, wherein the electrically conductive layer is optically reflective.

12. A method for producing an electronic device, including the implementation of a method according to claim 1, wherein the steps performed form a plurality of the photoemitting diodes and/or a plurality of the photoreceiving diodes, wherein the first electrodes of said diodes are electrically connected to each other.

13. The method according to claim 1, wherein producing, in the trenches, by deposition of the metal to form the at least one electrode comprises depositing the metal directly on the portions of the second part of the first layer not covered by the at least on dielectric spacer exposed in the etching extending the trenches and the contact surfaces of the second part of the first layer in the lateral etching.

14. The method according to claim 1, wherein the laterally etching forms a layer of the at least one dielectric spacer approximately 10 nm thick on the side walls.

15. The method of claim 9, wherein the at least one electrically conductive material is selected from one or more of titanium, copper, and aluminum.
